(19) United States
(12) Patent Application Publication
(10) Pub. No.: US 2011/0076850 A1
(43) Pub. Date: Mar. 31, 2011

(54) METHOD OF FABRICATING SEMICONDUCTOR DEVICE

(76) Inventor: Keiko SUMIOKA, Mie (JP)

(21) Appl. No.: 12/791,434

(22) Filed: Jun. 1, 2010

(30) Foreign Application Priority Data
Sep. 25, 2009 (JP) 2009-220508

(51) Int. Cl. H01L 21/311

(52) U.S. Cl. 438/703; 257/E21.257

(57) ABSTRACT

In one embodiment, a method of fabricating a semiconductor device is disclosed. The method can selectively form a core material made of carbon-containing material above a workpiece member. Additionally, the method can form a protective film made of material containing no oxygen so as to cover an upper surface and side faces of the core material. Furthermore, the method can form an oxide film so as to cover the core material and the workpiece member via the protective film. Moreover, the method can shape at least the oxide film into a sidewall in a position lateral to the core material. In addition, the method can etch the workpiece member by using the sidewall as a mask after removal of at least the core material, thereby transferring a pattern of the sidewall to the workpiece member.

### CROSS-REFERENCE TO RELATED APPLICATIONS

This application is based upon and claims the benefit of priority from prior Japanese Patent Application No. 2009-220508, filed on Sep. 25, 2009, the entire contents of which are incorporated herein by reference.

### FIELD

Embodiments described herein relate generally to a method of fabricating a semiconductor device.

### BACKGROUND

In recent years, formation technique for patterns having a dimension less than the resolution limit of a lithography exposure apparatus has been required with shrink of semiconductor devices. Sidewall transfer process, in which a sidewall pattern is formed on the side surfaces of a core material as a dummy pattern, and then a workpiece member is etched by using the sidewall pattern for a mask, is known as one of the formation techniques. The sidewall transfer process, for example, is disclosed in JP-A-2009-152243.

In the technique disclosed in JP-A-2009-152243, a core made of organic material is used. Number of fabrication processes and fabrication cost are lower when organic material is used for a core material than when inorganic material is used.

On the other hand, in recent years, use of an oxide film, which has high etching selectivity to a core material made of organic material and has good coatability, for a material of a sidewall pattern is under consideration.

However, when the sidewall pattern is formed from a material containing oxygen such as an oxide film, the core material made of organic material may be damaged due to oxide component contained the gas used for forming of the sidewall pattern, thereby causing decrease of the width thereof, deformation thereof (for example, deformation into convex shapes by shoulder dropping) or the like. In this case, the sidewall formed on the side surfaces of the core material loses the shape thereof, and thus an accurate and fine pattern can not be transferred to a workpiece member.

### BRIEF DESCRIPTION OF THE DRAWING

FIGS. 1A to 1F are cross sectional views showing processes for fabricating a semiconductor device according to a first embodiment;

FIGS. 2A to 2D are cross sectional views showing processes for fabricating a semiconductor device according to a second embodiment; and

FIG. 3 is a cross sectional view showing a process for fabricating the semiconductor device according to the second embodiment.

### DETAILED DESCRIPTION

In one embodiment, a method of fabricating a semiconductor device is disclosed. The method can selectively form a core material made of carbon-containing material above a workpiece member. Additionally, the method can form a protective film made of material containing no oxygen so as to cover an upper surface and side faces of the core material. Furthermore, the method can form an oxide film so as to cover the core material and the workpiece member via the protective film. Moreover, the method can shape at least the oxide film into a sidewall in a portion lateral to the core material. In addition, the method can etch the workpiece member by using the sidewall as a mask after removal of at least the core material, thereby transferring a pattern of the sidewall to the workpiece member.

### First Embodiment

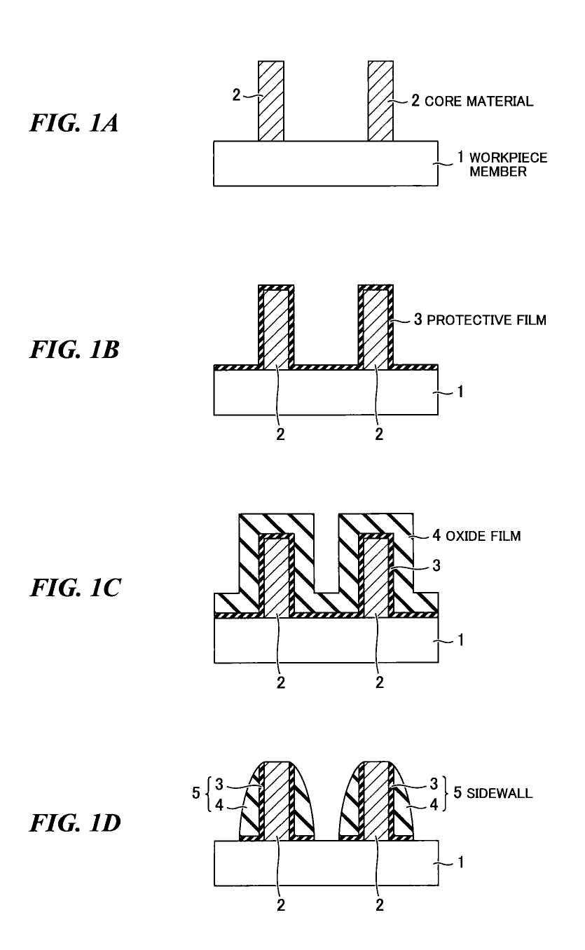

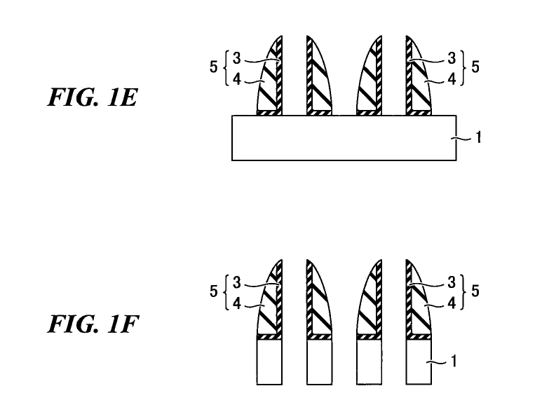

FIGS. 1A to 1F are cross sectional views showing processes for fabricating a semiconductor device according to a first embodiment.

Firstly, as shown in FIG. 1A, a core material 2 having a pattern such as a line-and-space pattern is selectively formed on a workpiece member 1 formed on, for example, a non-illustrated semiconductor substrate.

The workpiece member 1 is a gate material film, a hardmask on a workpiece, or the like. Furthermore, The workpiece member 1 may be a multilayer film including, for example, a control gate electrode film, an inter-electrode insulating film and a floating gate electrode film which constitute a stacked-gate structure of a flash memory. Moreover, the workpiece member 1 may be a semiconductor substrate.

Furthermore, the core material 2 is formed by patterning a material film made of carbon-containing material (organic material) such as resist material. Number of fabrication processes and fabrication cost are lower when organic material is used for the core material 2 than when inorganic material is used. A width of the core material 2 corresponds to a width of spaces in a line-and-space pattern formed on the workpiece member 1 in a posterior process.

The material film of the core material 2 is formed by Chemical Vapor Deposition (CVD) method, etc. The patterning of the material film is carried out by, for example, photolithography and Reactive Ion Etching (RIE).

Next, as shown in FIG. 1B, a protective film 3 is formed so as to conformally cover an upper surface and side faces of the core material 2 by the CVD method, etc.

The protective film 3 is made of material that contains no oxygen and has oxidation resistivity such as SiCN, SiN, SiC, BN, SiH or SiF. The protective film 3 is preferably formed in a thickness of 1 to 5 nm. When the thickness of the protective film 3 is less than 1 nm, the thickness is too thin to protect the core material 2 from oxide component described below. On the other hand, when the thickness is greater than 5 nm, it is difficult for the protective film 3 to conformally cover the surface of the core material 2, which may decrease uniformity of the thickness.

A specific example of formation process of the protective film 3 will be described hereinafter. Firstly, the semiconductor substrate is heated under a pressure not more than 10 Torr in non-illustrated reaction chamber. In this step, when the core material 2 is made of resist material, the heating temperature is set in 100° C. or less because resist material begin to be decomposed at temperature of around 100° C. The reaction chamber has parallel plate type electrodes in the upper and lower parts thereof, and the semiconductor substrate is put between those electrodes. The lower electrode functions also as a heater for heating semiconductor substrate.

Next, source gas for the protective film 3 is flowed in the reaction chamber, and then radiofrequency power is supplied under a condition in which pressure is maintained constant, thereby forming plasma area. When a SiCN film is formed as the protective film 3, mixed gas of trimethylsilane, ammonia and the He is used as the source gas. As a result, the protective film 3 is formed.

Next, as shown in FIG. 1C, an oxide film 4 made of silicon oxide is formed on the protective film 3 by CVD method, etc. A sum of the thickness of the protective film 3 and a thickness of the oxide film 4 corresponds to a width of lines of the line-and-space pattern formed on the workpiece member 1 in a posterior process.

The oxide film 4 has high etching selectivity to the core material 2 made of carbon-containing material. In addition, the oxide film 4 can be formed so as to conformally cover a surface of the protective film 3 with enough thickness (e.g., 24 nm) to be shaped into a sidewall 5 described below because the oxide film 4 has high coatability.

Note that, the material of the protective film 3, which contains no oxygen and has oxidation resistivity, such as SiCN, SiN, SiC, BN, SiH or SiF has low coatability, or high-temperature process is needed for conformally forming a thick film. Accordingly, it is difficult to use the material of the protective film 3 for a major material of a sidewall thicker than the protective film 3.

A specific example of formation process of the oxide film 4 will be described hereinafter. Firstly, the semiconductor substrate is heated under a pressure condition not more than 10 Torr in the non-illustrated reaction chamber. In this step, when the core material 2 is made of resist material, the heating temperature is set in 100° C. or less because resist material begin to be decomposed at temperature of around 100° C.

Next, source gas for the oxide film 4 is flowed in the reaction chamber, and then radiofrequency power is supplied under a condition in which pressure is maintained constant, thereby forming plasma area. For example, organosilane gas and mixed gas of O₂, He and Ar is used as the source gas for the oxide film 4. In this step, a base film is formed from organosilane gas, and then the base film is subjected to plasma treatment. The oxide film 4 that is dense and conformal is formed by repeating this process.

Here, although the gas used for forming the oxide film 4 contains oxide component, damage to the core material 2, which is made of carbon-containing material, caused by the oxide component can be suppressed because the surface of the core material 2 is covered by the protective film 3. Accordingly, decrease of the width of the core material 2 and deformation of the core material 2 can be suppressed.

Next, as shown in FIG. 1D, the protective film 3 and the oxide film 4 are shaped, thereby forming the sidewall 5 on side surfaces of the core material 2. Here, the sidewall 5 is composed of the shaped oxide film 4 and the shaped protective film 3, which is under the shaped oxide film 4 and on side surfaces of the core material 2. In this step, the sidewall 5 having an accurate pattern can be formed because decrease of the width and deformation do not occur on the core material 2.

Next, as shown in FIG. 1E, the core material 2 is removed. For example, O₂ aching, SH (water solution of sulfuric acid and hydrogen peroxide) process or a combination thereof is used for removing of the core material 2.

Next, as shown in FIG. 1F, the workpiece member 1 is etched by using the sidewall 5 as a mask, thereby transferring the pattern of the sidewall 5 to the workpiece member 1. Note that, when the pattern transferred to the workpiece member 1 is a ring pattern, a line-and-space pattern can be obtained by removing the ends of the ring pattern by lithography method and RIE method, or the like.

A result of experiments for demonstration of protective effect of the core material 2 by the protective film 3 will be described hereinafter. Firstly, a 24 nm thick oxide film has been formed on a carbon film, which had been formed at a temperature of 400° C., by CVD method at a temperature of 200° C. As a result, a 300 nm thick upper portion of the carbon film was eroded by oxide film, thereby changed to silicon oxide (the thickness of the upper portion changing to silicon oxide varies with a formation condition of each of the films). Secondly, a 24 nm thick oxide film was formed on a carbon film, which had been formed at a temperature of 400° C., via a 8 nm thick SiCN film, which had been formed at a temperature of 350° C., at a temperature of 200° C. As a result, condition of the carbon film was hardly changed even after the formation of the oxide film.

This result showed that the SiCN film functioned as a protective film for the carbon film. In addition, even if a film made of material that contains no oxygen and has oxidation resistivity such as SiN, SiC, BN, SiH or SiF had been used instead of the SiCN film, the same result would have been obtained.

### Second Embodiment

A second embodiment is different from the first embodiment in composition of a sidewall. Note that, the explanations will be omitted or simplified for the points same as the first embodiment.

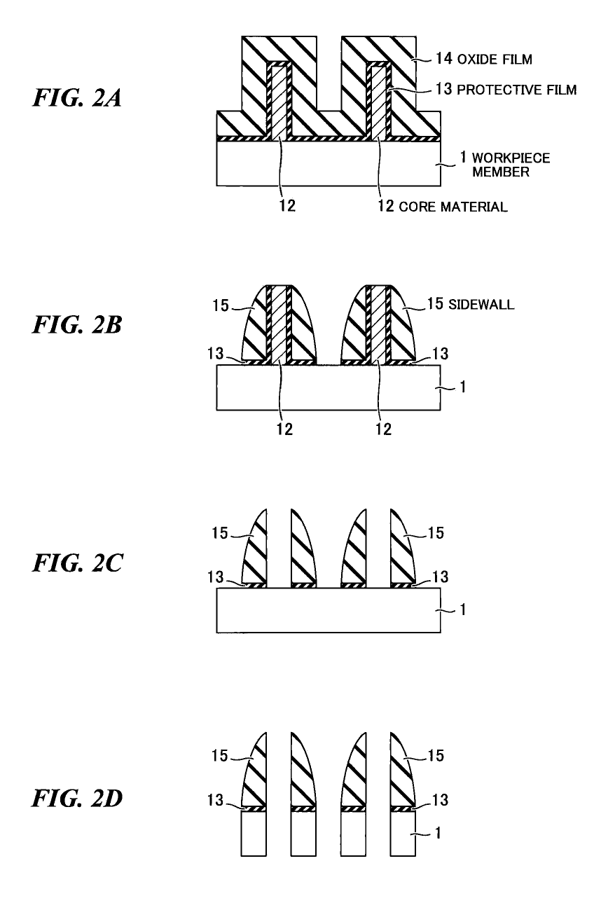

FIGS. 2A to 2D are cross sectional views showing processes for fabricating a semiconductor device according to a second embodiment.

Firstly, as shown in FIG. 2A, the core material 12, the protective film 13 and the oxide film 14 are respectively formed on the workpiece member 1 by the same methods as the core material 2, the protective film 3 and the oxide film 4. The protective film 13 is made of material that can be removed together with the core material 12 in a process in which the core material 12 is removed by etching.

Here, a sum of a width of the core material 12 and a thickness of the protective film 13 corresponds to a width of spaces of a line-and-space pattern formed on the workpiece member 1 in a posterior process. In addition, a width of the oxide film 14 corresponds to a width of lines of the line-and-space pattern.

Next, as shown in FIG. 2B, the oxide film 14 is shaped by RIE methods, etc., thereby forming a sidewall 15 consisting of the shaped oxide film 14 in a position lateral to the core material 12. In this step, the protective film 13 is shaped together with the oxide film 14, and removed while a portion thereof under the sidewall 15 and a portion thereof on side surfaces of the core material 12 are left.

Next, as shown in FIG. 2C, the core material 12 is removed. In this step, the portion of the protective film 13 on side surfaces of the core material 12 is removed together with the core material 12.

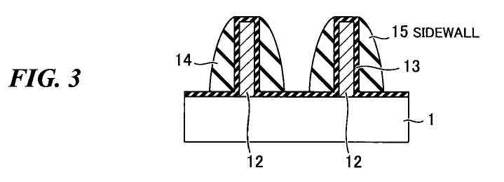

Note that, as shown in FIG. 3, firstly, the sidewall 15 may be formed in the position lateral to the core material 12 by shaping only the oxide film 14. Then, the portion of the protective film 13 other than the portion under the sidewall 15 is removed together with the core material 12, obtaining the same structure as shown in FIG. 2C. In each case, the portion of the protective film 13 other than the portion under the sidewall 15 and the core material 12 are removed after the sidewall 15 consisting of the oxide film 14 is formed.

Next, as shown in FIG. 2D, the workpiece member 1 is etched by using the sidewall 15 as a mask, thereby transferring the pattern of the sidewall 15 to the workpiece member 1.

Note that, when the workpiece member 1 is made of material that contains no oxygen and has oxidation resistivity like the protective film 13, the protective film 13 can be made of the same material as the workpiece member 1. In this case, the removal of the core material 12 and the protective film 13 on side surfaces thereof and the transfer of the pattern of the sidewall 15 to the workpiece member 1 can be collectively carried out.

According to the first and second embodiments, the surface of the core material is covered by the protective film before the oxide film is formed, and thus damage to the core material, which is made of carbon-containing material, caused by the oxide component can be suppressed. Accordingly, decrease of the width of the core material and deformation of the core material can be suppressed, thus the sidewall having an accurate pattern can be formed, and as a result, an accurate and fine pattern can be transferred to the workpiece member.

While certain embodiments have been described, these embodiments have been presented by way of example only, and are not intended to limit the scope of the inventions. Indeed, the novel methods described herein may be embodied in a variety of other forms; furthermore, various omissions, substitutions and changes in the form of the methods described herein may be made without departing from the spirit of the inventions. The accompanying claims and their equivalents are intended to cover such forms or modifications as would fall within the scope and spirit of the inventions.

What is claimed is:

1. A method of fabricating a semiconductor device, comprising:
selectively forming a core material made of carbon-containing material above a workpiece member;
forming a protective film made of material containing no oxygen so as to cover an upper surface and side faces of the core material;
forming an oxide film so as to cover the core material and the workpiece member via the protective film;
shaping at least the oxide film into a sidewall in a position lateral to the core material; and
etching the workpiece member by using the sidewall as a mask after removal of at least the core material, thereby transferring a pattern of the sidewall to the workpiece member.

2. The method of fabricating a semiconductor device according to claim 1, wherein the core material is made of resist material.

3. The method of fabricating a semiconductor device according to claim 2, wherein the protective film and the oxide film are formed under a temperature not more than 100° C.

4. The method of fabricating a semiconductor device according to claim 1, wherein the protective film is made of material containing at least one of SiCN, SiN, SiC, BN, SiH and SiF.

5. The method of fabricating a semiconductor device according to claim 1, wherein the protective film is formed in a thickness of 1 to 5 nm.

6. The method of fabricating a semiconductor device according to claim 1, wherein a pattern of the core material is a line-and-space pattern;
the pattern of the sidewall is a ring pattern; and
the ring pattern transferred to the workpiece member is shaped into a line-and-space pattern by removing the ends thereof.

7. A method of fabricating a semiconductor device, comprising:
selectively forming a core material made of carbon-containing material above a workpiece member;
forming a protective film made of material containing no oxygen so as to cover an upper surface and side faces of the core material;
forming an oxide film so as to cover the core material and the workpiece member via the protective film;
shaping the oxide film and the protective film into a sidewall in a position lateral to the core material; and
etching the workpiece member by using the sidewall as a mask after removal of the core material, thereby transferring a pattern of the sidewall to the workpiece member.

8. The method of fabricating a semiconductor device according to claim 7, wherein the sidewall is composed of the shaped oxide film and the shaped protective film, the shaped protective film being under the shaped oxide film and on side surfaces of the core material.

9. The method of fabricating a semiconductor device according to claim 7, wherein the core material is made of resist material.

10. The method of fabricating a semiconductor device according to claim 9, wherein the protective film and the oxide film are formed under a temperature not more than 100° C.

11. The method of fabricating a semiconductor device according to claim 7, wherein the protective film is made of material containing at least one of SiCN, SiN, SiC, BN, SiH and SiF.

12. The method of fabricating a semiconductor device according to claim 7, wherein the protective film is formed in a thickness of 1 to 5 nm.

13. The method of fabricating a semiconductor device according to claim 7, wherein a pattern of the core material is a line-and-space pattern;
the pattern of the sidewall is a ring pattern; and
the ring pattern transferred to the workpiece member is shaped into a line-and-space pattern by removing the ends thereof.

14. A method of fabricating a semiconductor device, comprising:
selectively forming a core material made of carbon-containing material above a workpiece member;
forming a protective film made of material containing no oxygen so as to cover an upper surface and side faces of the core material;
forming an oxide film so as to cover the core material and the workpiece member via the protective film;
shaping the oxide film into a sidewall in a position lateral to the core material; and
etching the workpiece member by using the sidewall as a mask after removal of the core material and a portion of the protective film other than a portion under the sidewall, thereby transferring a pattern of the sidewall to the workpiece member.

15. The method of fabricating a semiconductor device according to claim 14, wherein the protective film is removed while a portion thereof under the sidewall and a portion thereof on side surfaces of the core material are left when the oxide film is shaped into the sidewall; and
the workpiece member is etched by using the sidewall as a mask after removal of the core material and the portion of the protective film on the side surfaces of the core material.

16. The method of fabricating a semiconductor device according to claim 14, wherein the core material is made of resist material.

17. The method of fabricating a semiconductor device according to claim 16, wherein the protective film and the oxide film are formed under a temperature not more than 100° C.

18. The method of fabricating a semiconductor device according to claim 14, wherein the protective film is made of material containing at least one of SiCN, SiN, SiC, BN, SiH and SiF.

19. The method of fabricating a semiconductor device according to claim 14, wherein the protective film is formed in a thickness of 1 to 5 nm.

20. The method of fabricating a semiconductor device according to claim 14, wherein the workpiece member is made of the same material as the protective film;
the removal of the portion of the protective film other than the portion under the sidewall and the transfer of the pattern of the sidewall to the workpiece member are collectively carried out.
